(19) United States
(12) Patent Application Publication
(10) Pub. No.: US 2025/0006700 A1
(43) Pub. Date: Jan. 2, 2025

(54) SEMICONDUCTOR STACKING STRUCTURE AND MANUFACTURING METHOD THEREOF

(71) Applicant: Taiwan Semiconductor Manufacturing Company, Ltd., Hsinchu (TW)

(72) Inventors: Chen-Sheng Lin, Taoyuan City (TW); Ning Jiang, Taipei City (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/342,751

(22) Filed: Jun. 28, 2023

(51) Int. Cl. H01L 25/065; H01L 21/56; H01L 21/78; H01L 23/00; H01L 23/48; H01L 23/58

(52) U.S. Cl. CPC H01L 25/0657; H01L 21/561; H01L 21/78; H01L 23/481; H01L 23/585; H01L 24/08; H01L 24/94; H01L 2224/08145; H01L 2224/94

(57) ABSTRACT

A stacking structure including a first die and a second die bonded with the first die is provided. The first die has a first region and a second region encircled by the first region. The first die includes first metallization structures having a first seal ring structure and a first bonding structure having first dummy pads located over the first seal ring structure. The second die includes second metallization structures having a second seal ring structure and a second bonding structure having second dummy pads located over the second seal ring structure. The first die and the second die are bonded through bonding of the first and second bonding structures. The first and second seal ring structures are substantially vertically aligned, and the first dummy pads are respectively bonded with the second dummy pads.

### BACKGROUND

Packaging technologies involve packing and incorporating different types of stacked semiconductor dies with integrated circuits (ICs) and electronic devices. Durable integration with reliable electrical inter-connection between the semiconductor dies and other devices are important for the packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an exemplary packaging component with multiple semiconductor dies in accordance with some embodiments of the present disclosure.

FIGS. 2-9 are schematic cross-sectional views and top views showing various stages of the manufacturing method for forming a semiconductor stacking structure according to some embodiments of the present disclosure.

FIG. 10, FIG. 11 and FIG. 12 illustrate cross-sectional views of exemplary stacking structures in accordance with some embodiments of the present disclosure.

FIG. 13, FIG. 14 and FIG. 15 illustrate schematic cross-sectional views of portions of exemplary stacking structures in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

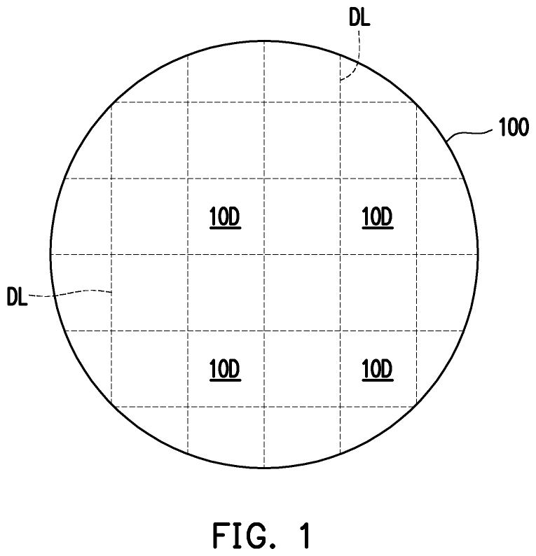

FIG. 1 is a schematic top view of an exemplary packaging component with multiple semiconductor dies in accordance with some embodiments of the present disclosure.

In FIG. 1, a packaging component is provided and may be used to form a stacking structure or a package structure in packaging processes. In some embodiments, the packaging component is a wafer 100 with multiple semiconductor dies 10D defined or formed within. In some embodiments, the wafer 100 is a semiconductor bulk wafer with active devices and optional passive devices formed therein. In some embodiments, the wafer 100 may be a reconstructed wafer. As seen in FIG. 1, the dashed lines represent dicing lanes DL by which the wafer 100 will be diced in a subsequent singulation process to obtain the semiconductor dies 10D that are separated from each other through the singulation process. In some embodiments, the semiconductor dies 10D have the same design and perform the same function. In some embodiments, the semiconductor dies of the wafer 100 have different designs and perform different functions.

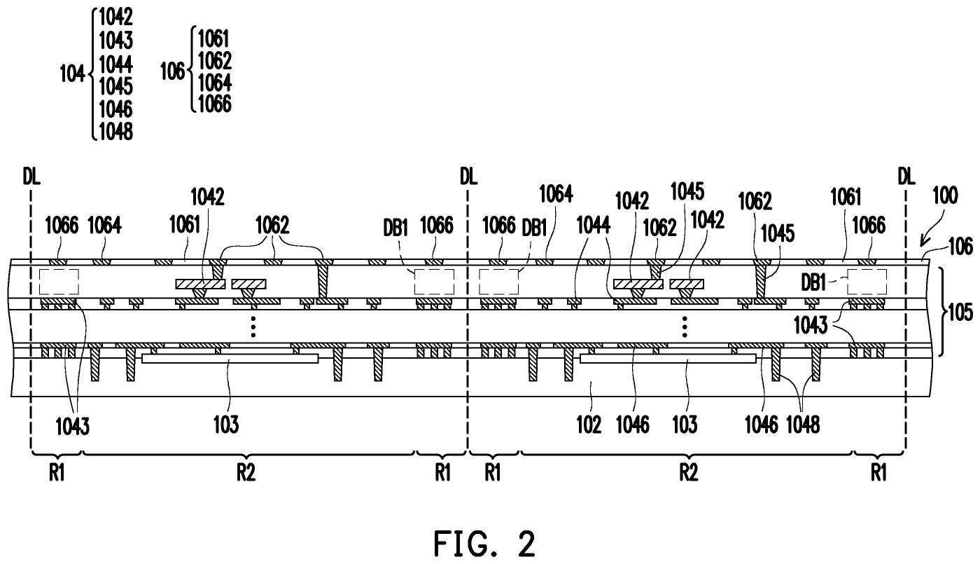

FIGS. 2-9 are schematic cross-sectional views and top views showing various stages of the manufacturing method for forming a semiconductor stacking structure according to some embodiments of the present disclosure. The same components or elements of similar or the same structure configuration(s) may be labeled with the same reference labels in the drawings.

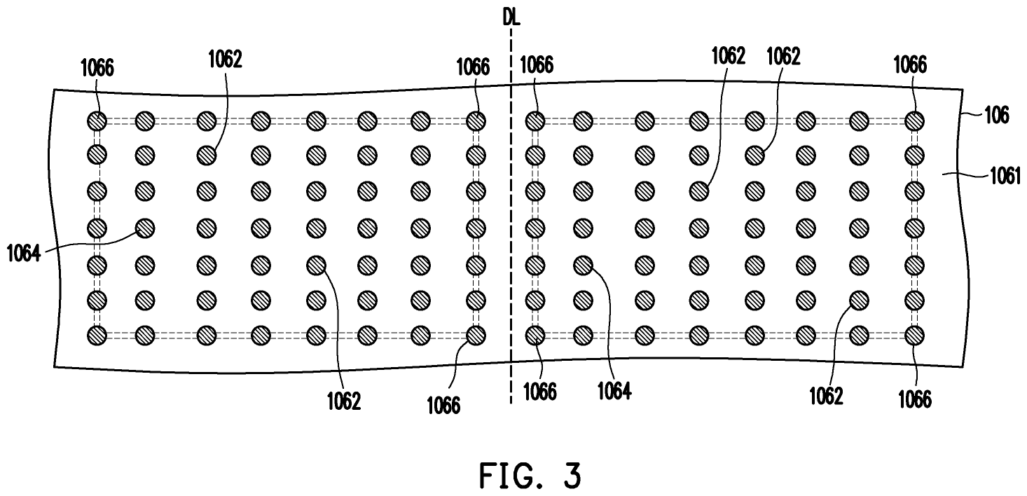

FIG. 2 is a schematic cross-sectional view showing an intermediate stage of the manufacturing method for forming a semiconductor stacking structure according to some embodiments of the present disclosure. FIG. 3 illustrates a schematic top view of one exemplary arrangement of the first bonding structure relative to the underneath element(s). In FIG. 2, in some embodiments, a wafer 100 is provided, and the wafer 100 is similar to the wafer 100 described in previous paragraph(s). In some embodiments, the wafer 100 is a semiconductor wafer, and the wafer 100 includes a semiconductor substrate 102 with an device layer 103, metallization structures 104 formed over the semiconductor substrate 102 and the active device layer 103, and first bonding structures 106 formed on the metallization structures 104 and over the semiconductor substrate 102. In some embodiments, the wafer 100 is a silicon wafer, or a bulk wafer made of other semiconductor materials such as III-V semiconductor materials such as gallium nitride (GaN) or gallium arsenide (GaAs). In some embodiments, the substrate 102 may be a monocrystalline semiconductor substrate such as a silicon substrate, a silicon-on-insulator (SOI) substrate, silicon-germanium on insulator (SGOI) or a germanium-on-insulator (GOI) substrate. In certain embodiments, the device layer 103 includes semiconductor devices formed in or on the semiconductor substrate 102 of the wafer 100 during the front-end-of-line (FEOL) processes. In certain embodiments, the semiconductor devices are or include transistors, memories or power devices, or other devices such as capacitors, resistors, diodes, photo-diodes, sensors, inductors or fuses. In exemplary embodiments, some of the semiconductor devices may be electrically connected with the metallization structures 104.

In some embodiments, the wafer 100 may be considered to have a plurality of semiconductor dies 10D before dicing or singulation. In FIG. 2, a portion of the wafer 100 including at least two die units are shown with the dicing lanes DL. In some embodiments, each die unit includes a first region R1 and a second region R2. In some embodiments, the second region R2 is or includes a main region formed with devices, and the first region R1 is or includes a peripheral region having no active devices or passive devices formed therein. In one embodiment, the first region R1 surrounds the second region R2. In one embodiment, the first region R1 includes structural features or components but has no electrically functional elements. It is understood that the number of the semiconductor dies 10D is merely exemplary, and the semiconductor dies 10D may include the same type of dies or dies of the same functions.

As shown in FIG. 2, in certain embodiments, the metallization structures 104 are embedded within an insulation material 105 formed on the semiconductor substrate 102. In some embodiments, the metallization structures 104 include multiple metallization layers of interconnect structures, including interconnected metal lines, vias and contact pads (the detailed configurations and interlayers are omitted and represented by the ellipsis dots). In some embodiments, in the second region R2, the metallization structures 104 include contact pads 1042 formed on the top metal lines 1044, bottom metal lines 1046 electrically connected to the device layer 103 and through semiconductor vias (TSVs) 1048 connected to the bottom metal lines 1046. In exemplary embodiments, the semiconductor devices in the device layer 103 are electrically connected with the bottom metal lines 1046 and with the metallization structures 104 and some of the semiconductor devices may be electrically interconnected through the bottom metal lines 1046 and the metallization structures 104. In some embodiments, the metallization structures 104 electrically connect the semiconductor devices of the device layer 103 with the above first bonding structures 106.

In some embodiments, in the first region R1, the metallization structures 104 include stacked seal ring structures 1043. In some embodiments, the stacked seal ring structures 1043 are electrically floating, even though they may be stacked upon and connected to each other. In some embodiments, the seal ring structures 1043 function as structural elements for reinforcing the structural strength and the rigidity of the die unit during later dicing or singulation process(es). As seen in FIG. 2, the seal ring structures 1043 are located beside and by the dicing lanes DL.

As shown in FIG. 2 and FIG. 3, in some embodiments, the first bonding structures 106 are formed over the insulation material 105 and the metallization structures 104. In exemplary embodiments, the first bonding structures 106 include interfacial bonding structures, and the first bonding structures 106 include a dielectric material 1061, bonding pads, dummy bonding pads 1064 and dummy pads 1066 embedded in the dielectric material 1061. In some embodiments, the bonding pads 1062, dummy bonding pads 1064 and dummy pads 1066 that penetrate through the dielectric material 1061 are exposed for contacting other metallic bonding pads, which functions as metallic-to-metallic bonding. In some embodiments, the dielectric material 1061 of the first bonding structures 106 may contact other dielectric material and function as dielectric-to-dielectric bonding. In exemplary embodiments, the first bonding structures 106 function as hybrid bonding structures.

Referring to FIG. 2 and FIG. 3, in some embodiments, the first bonding structures 106 include dummy pads 1066 that assist interfacial bonding but are not electrically functioning, and the dummy pads 1066 are arranged in the first region R1 and above the seal ring structures 1043. Using a tetragonal or rectangular die unit as an example, the dicing lanes DL are set by the four sides of the die unit, and the seal ring structures 1043 may be formed with a continuous ring-shape structure or as segments and arranged as a ring shape (represented by the double dashed lines in FIG. 3) by the dicing lanes DL and along the dicing lanes DL, some dummy pads 1066 are arranged along the ring-shaped structure of the seal ring structures 1043. In some embodiments, some dummy pads 1066 are located right above the seal ring structures 1043. In some embodiments, within the second region R2, the first bonding structures 106 also include bonding pads 1062 that are electrically connected the underneath metallization structures 104 or with other bonding pads of another die or packaging component, and dummy bonding pads 1064 that assist interface bonding but are not electrically functioning. That is, the dummy pads 1066 in the first region R1 and the dummy bonding pads 1064 in the second region R2 are neither part of the electrical signal path nor part of the power path of the dies or the stacking structure. In some embodiments, by way of vias 1045, some bonding pads 1062 are electrically connected with the contact pads 1042 or with the top metal lines 1044.

In certain embodiments, the materials of the metallization structures 104 include aluminum (Al), aluminum alloys, copper (Cu), copper alloys, titanium (Ti), nickel (Ni), tungsten (W), or combinations thereof. The metallization structures 104 shown herein are merely for illustrative purposes, and the metallization structures 104 may include other configurations and may include one or more through vias and/or damascene structures. In some embodiments, the contact pads 1042 include aluminum pads, the seal rings 1043 are formed from the same processes and are made of the same metal materials for the bottom metal lines 1046, the top metal lines 1044, the vias 1045 and metallic layers formed in-between. In some embodiments, the insulation material 105 includes one or more low-k dielectric layers. In some embodiments, the insulation material 105 includes silicon oxide, a spin-on dielectric material, a low-k dielectric material or a combination thereof.

As shown in FIG. 2, in some embodiments, within the second region R2, the metallization structures 104 include the contact pads 1042 formed over the top metal lines 1044, and the contact pads 1042 are input/output (I/O) pads or aluminum pads, for example. In exemplary embodiments, there are no contact pads formed in the first region R1 above the seal ring structures 1043, and only dummy pads 1066 are formed above the seal ring structures 1043. That is, within the first region R1, there is a pad-free or aluminum pad-free zone DB1 of the insulation material 105 right above the seal ring structures 1043 and sandwiched between the dummy pads 1066 and the top of the seal ring structures 1043. In some embodiments, such pad-free zone DB1 of the insulation material 105 is regarded as a metal-free dielectric buffer block, which help to isolate the contact pads in the second regions of different die units. As such metal-free dielectric blocks are located beside and at opposite sides of the dicing lane(s) DL, better buffering and less stress are offered, thus avoiding cracking or split of the dielectric film above the seal ring structures 1043 in the peripheral region of the die unit. Further, the arrangement of the dummy pads 1066 in the first region R1 (above the seal ring structures 1043) contributes to uniform layout of the pads and improves the consistency of the bonding interface, leading to better bonding reliability.

In some embodiments, the bonding pads 1062, dummy bonding pads 1064 and dummy pads 1066 are formed from the same process and are made of the same metallic material. For example, the metallic material includes copper, copper alloys, titanium (Ti), titanium nitride, nickel (Ni), or combinations thereof. In some embodiments, the dielectric material 1061 includes one or more oxide dielectric layers. In some embodiments, the dielectric material 1061 includes silicon oxide, silicon nitride, a spin-on dielectric material such as undoped silicate glass material, a low-k dielectric material or a combination thereof. In some embodiments, the dielectric material 1061 includes silicon oxide formed by CVD process using tetraethoxysilane (TEOS).

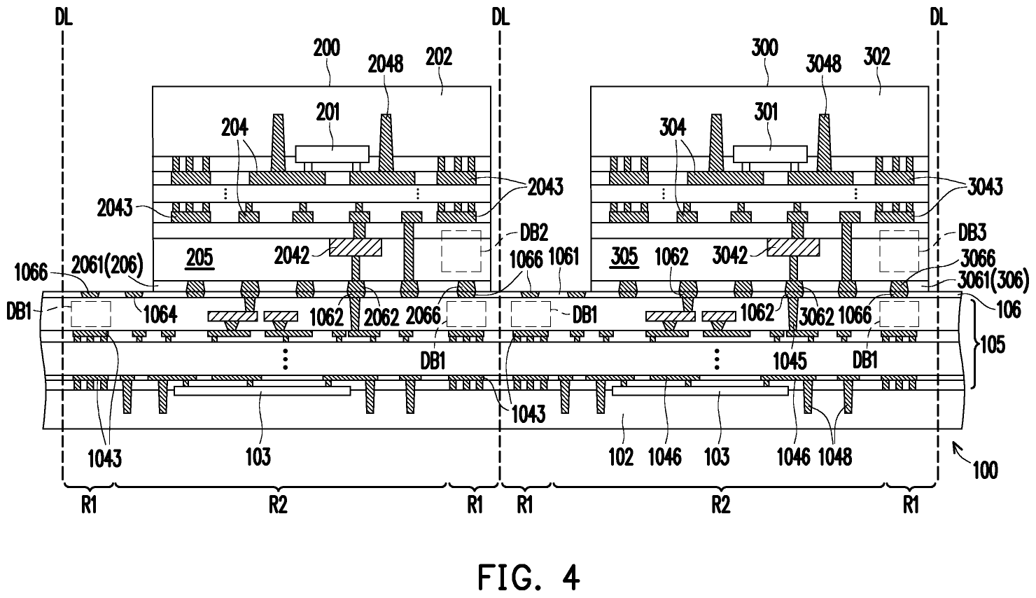

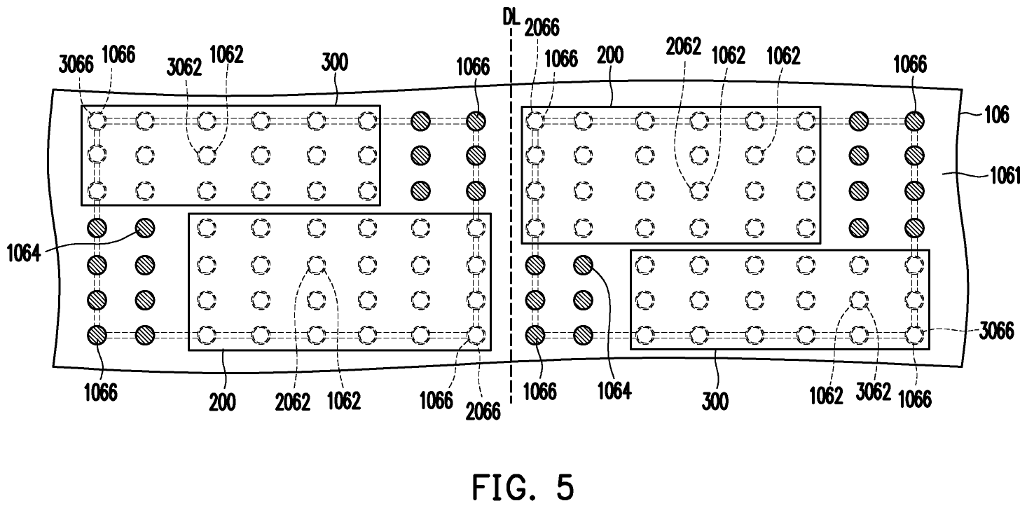

FIG. 4 is a schematic cross-sectional view showing an intermediate stage of the manufacturing method for forming a semiconductor stacking structure according to some embodiments of the present disclosure. FIG. 5 illustrates a schematic top view of one exemplary arrangement of the bonding structures relative to the underneath element(s). Referring to FIG. 4, in some embodiments, second dies 200 (only one is shown) and third dies 300 (only one is shown) are provided and stacked onto the wafer 100. For example, as seen in FIG. 5, multiple second dies 200 and multiple third dies 300 are disposed side-by-side on the top surface of the wafer 100. In some embodiments, depending on the product design, at least one second die 200 and at least one third die are included within one package unit.

In certain embodiments, each second die 200 includes a second semiconductor substrate 202, second metallization structures 204 embedded in the insulation material 205 formed on the second semiconductor substrate 202 and a second bonding structure 206 formed on the second metallization structures 204 (from top to bottom as the second die 200 faces down in FIG. 4). In embodiments, each second die 200 includes semiconductor devices 201 and isolation structures (not shown) formed in the semiconductor substrate 202. In certain embodiments, the second metallization structures 204 include stacked seal rings 2043, through semiconductor vias 2048 and interconnected metal lines and vias (the detailed configurations and interlayers are omitted and represented by the ellipsis dots). In some embodiments, the second bonding structure 206 includes a dielectric material 2061, bonding pads 2062 that are electrically connected with the second metallization structures 204 and semiconductor devices 201, and dummy bonding pads 2066 that are electrically floating and not electrically connected with the semiconductor devices 201.

In some embodiments, the second dies 200 are fabricated from a semiconductor wafer with similar configuration design as shown for the die unit(s) of the wafer 100. In some embodiments, the second die 200 includes a main region having the semiconductor devices 201 and aluminum pads 2042 formed therein. In some embodiments, the second die 200 includes a peripheral region having no active devices or passive devices formed therein but having stacked seal rings 2043 and dummy pads 2066 formed right below the stacked seal rings 2043. Also, in FIG. 4, there is a pad-free or aluminum pad-free zone DB2 right below the seal rings 2043 (the second die 200 facing down in FIG. 4) and sandwiched between the dummy pads 2066 and the top of the seal rings 2043. Similarly, when the stacked seal rings 2043 are formed into a ring-shape, the pad-free zone DB2 may be ring-shaped. In some embodiments, such pad-free zone DB2 of the insulation material 205 is regarded as a metal-free dielectric buffer block.

In certain embodiments, each third die 300 includes a third semiconductor substrate 302, third metallization structures 304 embedded in the insulation material 305 formed on the third semiconductor substrate 302 and a third bonding structure 306 formed on the third metallization structures 304 (from top to bottom as the third die 300 faces upside down in FIG. 4). In embodiments, each third die 300 includes semiconductor devices 301 and isolation structures (not shown) formed in the semiconductor substrate 302. In certain embodiments, the third metallization structures 304 include stacked seal rings 3043, through semiconductor vias 3048 and interconnected metal lines and vias (the detailed configurations and interlayers are omitted and represented by the ellipsis dots). In some embodiments, the third bonding structure 306 includes a dielectric material 3061. bonding pads 3062 that are electrically connected with the third metallization structures 304 and semiconductor devices 301, and dummy bonding pads 3066 that are electrically floating.

In some embodiments, the third dies 300 are fabricated from a semiconductor wafer with similar configuration design as shown for the die unit(s) of the wafer 100. In some embodiments, the third die 300 includes a main region having the semiconductor devices 301 and aluminum pads 3042 formed therein. In some embodiments, the third die 300 includes a peripheral region having no active devices or passive devices formed therein but having stacked seal rings 3043 and dummy pads 3066 formed right below the stacked seal rings 3043 (the third die 300 facing upside down in FIG. 4). Also, there is a pad-free or aluminum pad-free zone DB3 right below the seal rings 3043 and sandwiched between the dummy pads 3066 and the top of the seal rings 3043. Similarly, when the stacked seal rings 3043 are formed into a ring-shape, the pad-free zone DB32 may be ring-shaped. In some embodiments, such pad-free zone DB3 of the insulation material 305 is regarded as a metal-free dielectric buffer block.

In certain embodiments, the materials of the second metallization structures 204 or the third metallization structures 304 may be similar to or the same as that of the first metallization structures 104. In certain embodiments, the materials of the dielectric material and pads of the second bonding structure 206 or the third bonding structure 306 may be similar to or the same as those of the first bonding structures 106.

During the placement of the second dies 200 and the third dies 300, the second dies 200 and the third dies 300 are arranged to align the second bonding structures 206 and the third bonding structures 306 with the corresponding first bonding structures 106 respectively, so that the bonding pads and the dummy pads are respective die(s) are substantially vertically aligned (along the thickness direction) with the bonding pads and dummy pads of the wafer 100 respectively. In some embodiments, once the second dies 200 and the third dies 300 are placed on the wafer 100, the second bonding structures 206 and the third bonding structures 306 are in direct contact with the corresponding first bonding structures 106.

Then, in some embodiments, as shown in FIG. 4, a bonding process is performed to bond the first, second and third bonding structures 106, 206 and 306 to each other so as to bond the second dies 200 and the third dies 300 with the die units (semiconductor dies 10D) of the wafer 100. In some embodiments, the bonding process is or includes a hybrid bonding process. In one embodiments, during the application of hybrid bonding technology, a low temperature heating process at a temperature of about 100 degrees Celsius to about 200 degrees Celsius is performed to heat and bond the dielectric materials 1061, 2061, 3061 (dielectric-to-dielectric bonding) and a high temperature heating process is performed at a temperature of about 200 degrees Celsius to about 300 degrees Celsius to bond the metallic pads 1062, 1064, 1066, 2062, 2066, 3062, 3066 (metallic-to-metallic bonding). In some embodiments, the second dies 200 and the third dies 300 are bonded to the wafer 100 through hybrid interfacial bonding to form a die-stacked-on-wafer structure.

Referring to FIG. 4 and FIG. 5, after stacking second dies 200 and third dies 300 onto the wafer 100, the second bonding structure 206 and the third bonding structure 306 are aligned to and bonded to the first bonding structures 106. There is a hybrid bonding interface existing between the first bonding structures 106 and the second and third bonding structures 206 and 306. In some embodiments, by way of alignment, the dummy pads 2066 of the second bonding structure 206 and the dummy pads 3066 of the third bonding structure 306 are aligned to and bonded to the dummy pads 1066 of the first bonding structures 106. In some embodiments, by way of alignment, the bonding pads 2062 of the second bonding structure 206 and the bonding pads 3062 of the third bonding structure 306 are aligned to and bonded to the bonding pads 1062 of the first bonding structures 106. Through the bonding pads 1062, 2062, 3062, the second dies 200 and the third dies 300 are electrically connected with the underlying die units (or semiconductor dies 10D) of the wafer 100.

As seen in FIG. 4, after bonding, the stacked seal rings 2043 located within the first region R1 is substantially vertically aligned with the underlying seal ring structures 1043 (i.e. the locations are partially overlapped), and the pad-free zone DB2 within the first region RI is substantially vertically aligned with the pad-free zone DB1. After bonding, the bonded dummy pads 1066 and 2066 and the aligned pad-free zones DB1 and DB2 are located beside and by the dicing lanes DL. Also, the stacked seal rings 3043 located within the first region R1 is substantially vertically aligned with the underlying seal ring structures 1043, and the pad-free zone DB3 within the first region R1 is substantially vertically aligned with the pad-free zone DB1 after bonding. In some embodiments, after bonding, the bonded dummy pads 1066, 3066 and the aligned pad-free zones DB1 and DB3 are located beside and by the dicing lanes DL. Through the bonded dummy pads 1066, 2066 and 3066, better interfacial bonding is established and little cracking or delamination occurs due to the existence of the buffering dielectric blocks of the metal-free zones DB1, DB2 and DB3 located near the dicing lanes DL.

In some embodiments, as shown in FIG. 4 and FIG. 5, the area/size of the second die 200 or the third die 300 is smaller than the area/size of one die unit (cut into the semiconductor dies 10D) of the wafer 100, and the area/size of the second die 200 is larger than that of the third die 300. It is understood that the number of the second dies 200 or the third die 300 is merely exemplary. In some embodiments, the second dies 200 and the third dies are different type of dies from the semiconductor dies 10D. In some embodiments, the second dies 200 or third dies 300 may be the same type of dies as the semiconductor dies 10D but have different areas or spans from the area/span of the semiconductor dies 10D. In some embodiments, due to the size differences, some dummy pads 1066 and some dummy bonding pads 1064 are exposed and not covered by the mounted second dies 200 or third dies 300.

In some embodiments, the semiconductor dies 10D, the second dies 200 and the third dies 300 have different functions. In some embodiments, the semiconductor dies 10D and the second dies 200 or the third dies 300 have the same functions but are of different sizes. In some embodiments, the semiconductor dies 10D include logic dies, such as central processing unit (CPU) dies, graphic processing unit (GPU) dies, micro control unit (MCU) dies, baseband (BB) dies, or application processor (AP) dies. In some embodiments, the third dies 300 include memory dies, such as high bandwidth memory (HBM) dies, dynamic random access memory (DRAM) dies, or static random access memory (SRAM) dies. In some embodiments, the second dies 200 include application-specific integrated circuit (ASIC) dies, analog dies, sensor dies, wireless application dies (including Bluetooth chips and/or radio frequency chips) or voltage regulator dies.

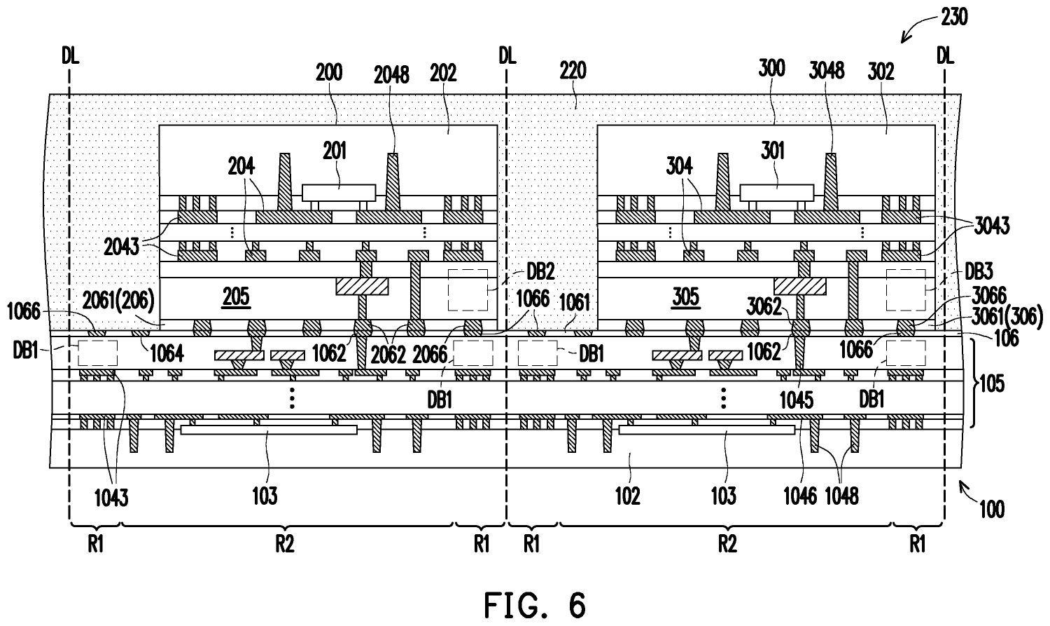

FIGS. 6-9 are schematic cross-sectional views showing various stages of the manufacturing method for forming a semiconductor stacking structure according to some embodiments of the present disclosure. Following FIG. 4 and referring to FIG. 6, a filling material 220 is formed over the die-stacked-on-wafer structure, especially filling the gaps between the second dies 200 and third dies 300 on the wafer 100, to form a molded structure 230. In one embodiment, the molded structure 230 is a reconstructed wafer structure. In some embodiments, the filling material 220 is an insulating material. In one embodiment, the filling material 220 is formed by chemical vapor deposition (CVD), spin coating or molding. In some embodiments, the filling material 220 fully covers the second dies 200 and the third dies 300 bonded to the wafer 100. In some embodiments, the filling material 220 covers the top surface of the wafer 100, fills the gaps between the second dies 200 and third dies 300 and covers the top surfaces and sidewalls of the second dies 200 and third dies 300. Also, the filling material 220 covers the uncovered bonding structures 106 of the wafer 100 and covers the exposed dummy pads 1066 and the dummy bonding pads 1064. In some embodiments, relative to the bonding interface, the pads are not arranged in a symmetrical form, and some dummy pads and/or some dummy bonding pads are in direct contact with the filling material. As seen in FIG. 6, the thickness of the filling material 220 is larger enough to be higher than the tops of either the second dies 200 or the third dies 300. In some embodiments, the material of the filling material 220 includes silicon oxide, silicon nitride, epoxy resins, phenolic resins or silicone resins.

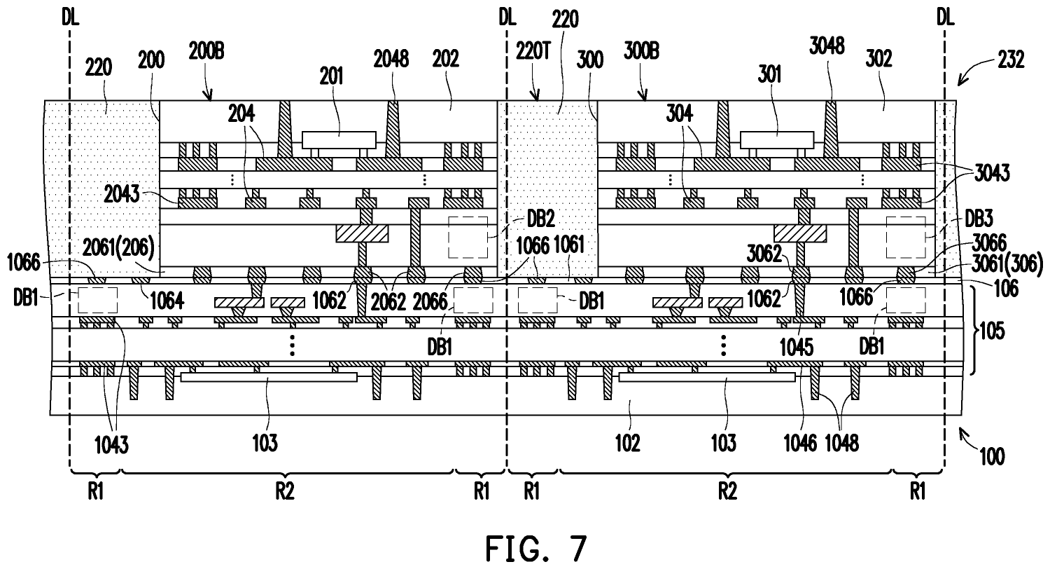

In some embodiments, referring to FIG. 7, a planarization process is performed to partially remove the filling material 220 as well as portions of the second dies 200 and the third dies 300 to form a planarized molded structure 232. The planarization process includes performing a grinding process or a polishing process such as a chemical mechanical polishing process, for example. After planarization, the backsides of the second dies 200 and the third dies are polished until the TSVs 2048 and 3048 are exposed. In some embodiments, the planarized filling material 220 at least laterally covers the sidewalls of the second dies 200 and the third dies 300 mounted on the wafer 100. In some embodiments, as seen in FIG. 7, the top surface 220T of the planarized filling material 220 is levelled with and flush with the backsides 200B of the second dies 200 and the backsides 300B of the third dies 300. As the filling material 220 is formed directly on the exposed bonding structures 106 of the wafer 100, there is dielectric-to-dielectric bonding between the exposed dielectric material 1061 and the filling material 220. In one embodiment, the dummy pads 1066 and the dummy bonding pads 1064 located below the filling material 220 are electrically floating pads. In some embodiments, these floating pads are electrically unconnected with any semiconductor devices and may assist thermal dissipation.

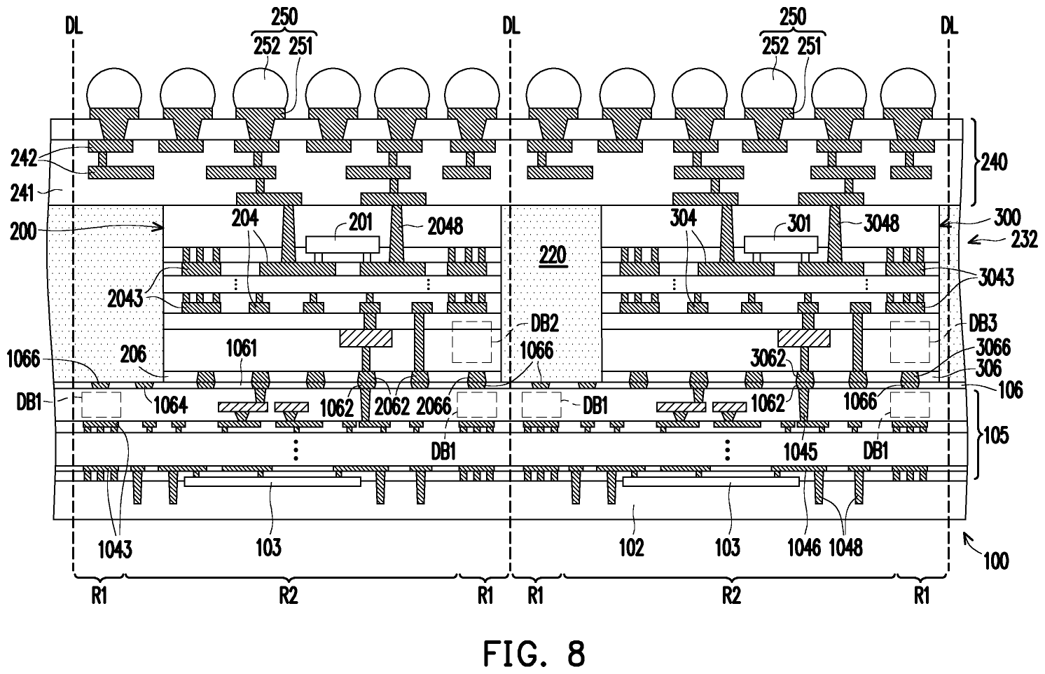

Referring to FIG. 8, in some embodiments, a redistribution layer (RDL) 240 is formed over the planarized molded structure 232 and is formed on the planarized filling material 220 and on the second and third dies 200 and 300. The redistribution layer (RDL) 240 is electrically connected to the second dies 200 and third dies 300 through at least the TSVs 2048 and 3048 of the second and third dies 200 and 300. In some embodiments, the RDL 240 includes redistribution metal patterns 242 embedded in a dielectric material layer 241. The configuration of the redistribution metal patterns is not limited by the disclosure, while the dielectric material layer may include more than one layers of dielectric materials. The redistribution metal patterns 242 includes routing metal patterns, vias and metal pads, for example. In certain embodiments, the dielectric material layer 241 exposes some of the underlying redistribution metal patterns 242, and conductive terminals 250 are formed on the exposed metal patterns 242. In some embodiments, the conductive terminal 250 includes a metal post 251 and a bump 252. In some embodiments, the material of the dielectric material layer 241 includes silicon oxide, silicon nitride, low-k dielectric materials, benzocyclobutene (BCB), epoxy, polyimide (PI), or polybenzoxazole (PBO). In some embodiments, a material of the metal post 251 includes copper or cooper alloys, and a material of the bump 252 includes solder. In one embodiment, the metal posts 251 and bumps 252 located on the metal posts 251 constitute micro bumps. In some embodiments, the conductive terminals 250 include copper pillar bumps.

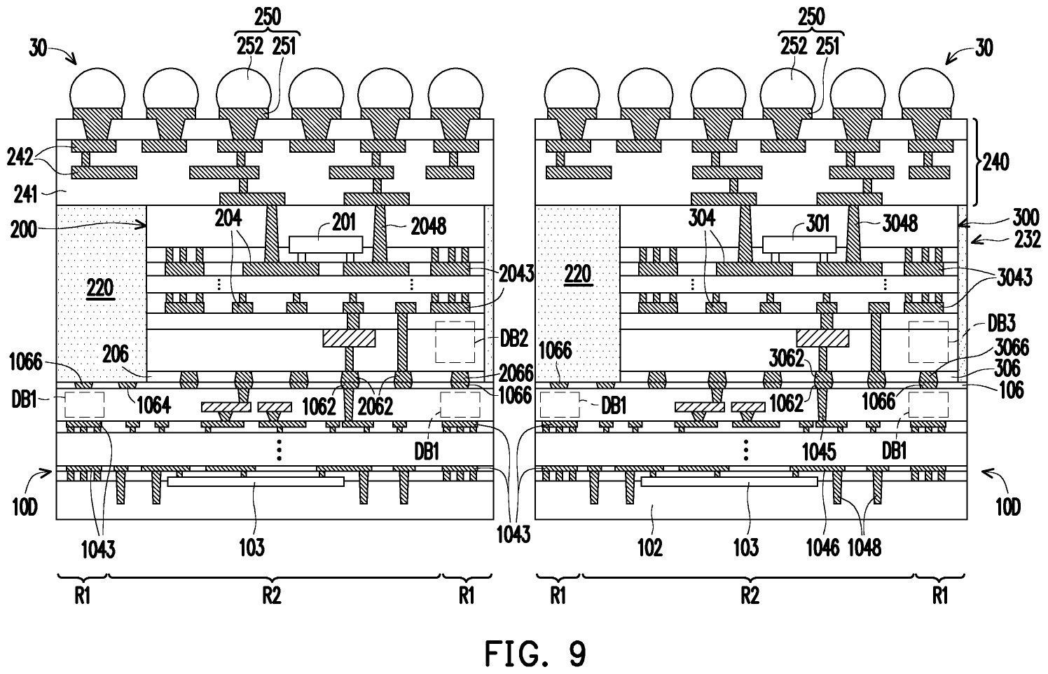

Later, in some embodiments, referring to FIG. 8 and FIG. 9, a singulation process is performed to cut the planarized molded structure 232 along the dicing lanes DL into individual three-dimensional (3D) stacking structures 30. In exemplary embodiments, in reference to the exemplary arrangement having at least one second die 200 and at least one third die included within one package unit as shown in FIG. 5, after singulation, each of the singulated 3D stacking structures 30 includes at least one second die 200 and at least one third die 300 stacked on the semiconductor die 10D and the filling material 220 wrapping around the second die 200 and the third die 300. In some embodiments, the singulation process includes a wafer dicing process or a sawing process. Due to the layout arrangement, from the cross-sectional view shown in FIG. 9, one of the two 3D stacking structures 30 is shown to include the second die 200, while the other 3D stacking structure 30 is shown to include the third die 300; however, it is understood that each stacking structure (package unit) includes at least one second die 200 and one third die 300.

In some embodiments, through the metallization structures 104, 204, 304 and hybrid bonding structures 106, 206, 306, electrical connection paths are established between the semiconductor dies 10D, 200 and 300 of the stacking structure 30. On the other hand, the seal ring structures 1043, 2043, 3043 and the bonded dummy pads 1066, 2066, 3066 are electrically floating and are not part of the electrical connection paths.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, whilst the illustrated processes belong to a chip-on-wafer (CoW) process and may be further fabricated into 3D stacking packages or chip-on-wafer-on-substrate (CoWoS) packages.

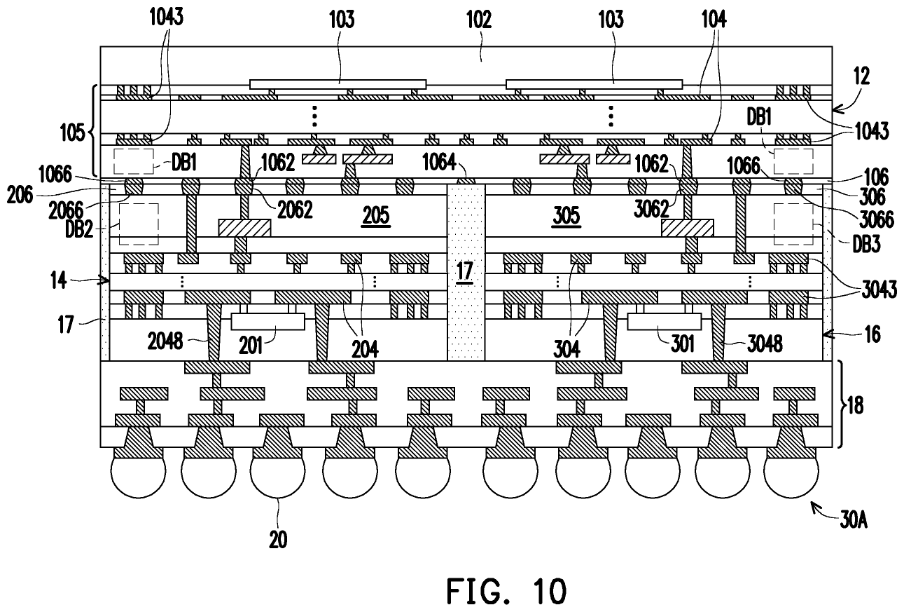

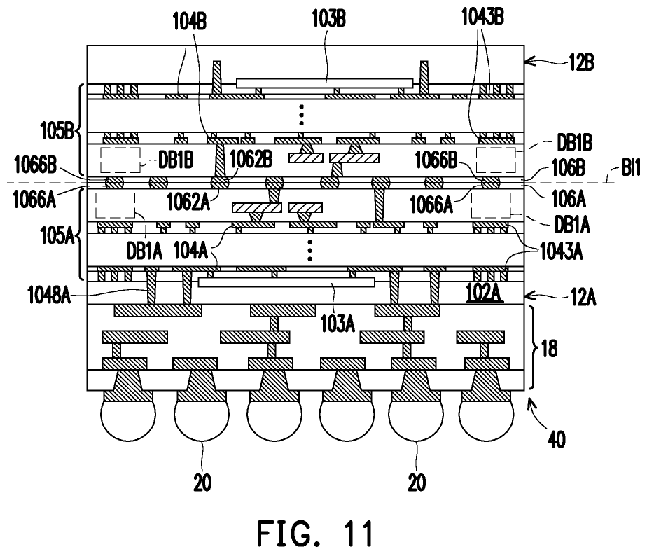

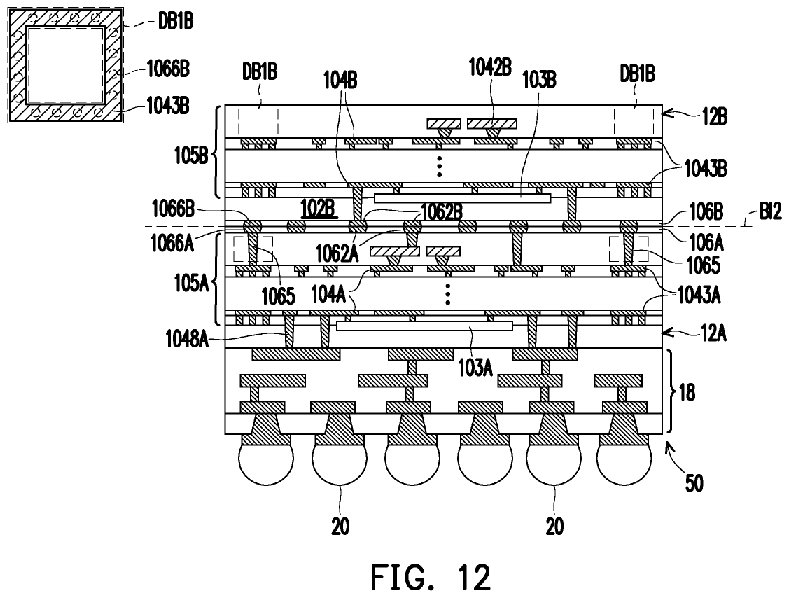

FIG. 10 illustrates a cross-sectional view of an exemplary 3D stacking structure in accordance with some embodiments of the present disclosure. In FIG. 10, the 3D stacking structure 30A comprises at least a first die 12, a second die 14 and a third die 16 disposed on the first die 12, and a filling material 17 filled between the second die 14 and the third die 16, wrapping around the second die 14 and the third die 16, and disposed on the first die 12. In some embodiments, the first die 12 is similar to the semiconductor die 10D described in the previous paragraphs except for having no TSVs, and the second and third dies 12, 14 are similar to the second and third dies 200, 300 described in the previous paragraphs. Herein, the same or similar structural features or elements may be labelled with the same reference numbers.

As seen in FIG. 10, the first die 12 includes the first bonding structures 106 having the dummy pads 1066 in the peripheral region, and first metallization structures 104 having the seal ring structures 1043 located right above the dummy pads 1066. Within the first die 12, there is a metal-free or metal pad-free zone DB1 of the insulation material 105 sandwiched between the dummy pads 1066 and the seal ring structures 1043. In some embodiments, the second die 14 includes the second bonding structure 206 having the dummy pads 2066 in the peripheral region, and second metallization structures 204 having stacked seal rings 2043 located right below the dummy pads 2066, and there is a metal free or metal pad-free zone DB2 of the insulation material 205 right above the seal rings 2043 and sandwiched between the dummy pads 2066 and the top of the seal rings 2043. In some embodiments, the third die 16 also includes the third bonding structure 306 having the dummy pads 3066 formed in the peripheral region and third metallization structures 304 having stacked seal rings 3043 located right below the dummy pads 3066. Also, there is a metal-free or metal pad-free zone DB3 of the insulation material 305 right above the seal rings 3043 and sandwiched between the dummy pads 3066 and the top of the seal rings 3043. In some embodiments, for the 3D stacking structure 30A, the substantially vertically aligned metal pad-free zones DB1, DB2. DB3 surrounding the peripheral region of the stacking structure 30A may function as metal-free dielectric blocks, which alleviates cracking or delamination at the edges of the stacking structure 30A (or package unit) and improves the production yield. In some embodiments, the bonded dummy pads 1066, 2066, 3066 together with the surrounding seal ring structures 1043, 2043, 3043 boost the bonding strength and improve the reliability of the stacking structure 30A.

In some embodiments, the third die 16 and the second die 14 are stacked face-to-face with the first die 12, and the third bonding structure 306 of the third die 16 and the second bonding structure 206 of the second die 14 are in contact with and directly connected with the first bonding structures 106 of the first die 12. That is, the first die 12 is hybrid-bonded with the second die 14 and the third die 16 with a hybrid bonding interface there-between. In some embodiments, the second die 14 and the third die 16 are electrically connected with the first die 12 through the metallization structures 104. 204, 304 and the bonding structures 106, 206, 306. In some embodiments, the filling material 17 sandwiched between the second die 14 and the third die 16 covers the exposed dummy bonding pad(s) 1064 and dummy pads 1066.

In certain embodiments, as shown in FIG. 10, the 3D stacking structure 30A further comprises a redistribution layer (RDL) 18 disposed on the second die 14, the third die 16 and the filling material 17, and conductive terminals 20 located on the RDL 18. For example, the conductive terminals 20 may be electrically connected with the second die 14 and the third die 16 through the RDL 18 and the TSVs 2048 and 3048 of the second and third dies 14 and 16.

FIG. 11 and FIG. 12 illustrate cross-sectional views of exemplary 3D stacking structures in accordance with some embodiments of the present disclosure. According to the embodiments, the same or similar elements may be labelled with the same reference numbers, and the details and descriptions of the same or similar elements will not be repeated herein for simplification.

In FIG. 11, the 3D stacking structure 40 comprises at least a first die 12A and a second die 12B located on the first die 12A. In some embodiments, the first die 12A and the second die 12B perform different functions but have substantially the same sizes. In some embodiments, the first die 12A and the second die 12B perform substantially the same or similar functions and have substantially the same sizes. For example, the first die 12A and/or the second die 12B may be similar to the semiconductor die 10D described in the previous paragraphs, but it is understood that certain structural features may have different configurations or modifications.

In some embodiments, the first die 12A includes a front-side bonding structure 106A, and the second die 12B includes a front-side bonding structure 106B. As seen in FIG. 11, the first die 12A and the second die 12B are bonded face-to-face through the first bonding structure 106A connected with the corresponding second bonding structure 106B with a bonding interface BI1. In one embodiment, the bonding interface BI1 is a hybrid bonding interface. In certain embodiments, the 3D stacking structure 40 comprises a redistribution layer (RDL) 18 disposed on the first die 12A, and conductive terminals 20 located on the RDL 18. In some embodiments, within the peripheral region of the 3D stacking structure 40, the seal ring structures 1043A of the first die 12A and the seal ring structures 1043B of the second die 12B are arranged as ring-shapes respectively along the peripheral regions of the first die 12A and the second die 12B. Also, the location of the seal ring structures 1043A is overlapped (partially or fully) with the location of the seal ring structures 1043B. It is possible that the seal ring structures 1043A and 1043B are arranged as rings stacked upon each other. In one embodiment, the seal ring structures 1043A and 1043B are substantially vertically aligned (along the thickness direction). In some embodiments, dummy pads 1066A of the first die 12A are bonded with the corresponding dummy pads 1066B of the second die 12B, and both dummy pads 1066A, 1066B are located between the seal ring structures 1043A, 1043B. Also, within the peripheral region of the 3D stacking structure 40, there is a metal-free zone DB1A that is sandwiched between the dummy pads 1066A and the seal ring structures 1043A, and there is a metal-free zone DB1B that is sandwiched between the dummy pads 1066B and the seal ring structures 1043B. In some embodiments, the dielectric-only zone DB1B of the insulation material 105B and the dielectric-only zone DB1A of the insulation material 105A are substantially vertically aligned.

In some embodiments, the semiconductor devices 103A of the first die 12A and the semiconductor devices 103B of the second die 12B are electrically connected through the metallization structures 104A and 104B and bonding pads 1062A and 1062B there-between. In some embodiments, the conductive terminals 20 are electrically connected with the first die 12A and the second die 12B through the RDL 18 and the TSVs 1048A penetrating through the semiconductor substrate 102A of the first die 12A.

In FIG. 12, the 3D stacking structure 50 comprises at least a first die 12A and a second die 12B located on the first die 12A. In some embodiments, the first die 12A and the second die 12B perform different functions but have substantially the same sizes. In some embodiments, the first die 12A and the second die 12B perform substantially the same or similar functions and have substantially the same sizes. For example, the first die 12A and/or the second die 12B may be similar to the semiconductor die 10D described in the previous paragraphs. As seen in FIG. 12, the first die 12A and the second die 12B are bonded face-to-back, and certain structural features are modified with different configurations from the die 10D.

In some embodiments, the first die 12A includes a front-side bonding structure 106A located above the metallization structures 104A, and the second die 12B includes a backside bonding structure 106B located below the metallization structures 104B and on the semiconductor substrate 102B. As seen in FIG. 12, the front-side of the first die 12A and the backside of the second die 12B are bonded through the connected bonding structures 106A and 106B with a bonding interface BI2. In one embodiment, the bonding interface BI2 is a hybrid bonding interface. In certain embodiments, the 3D stacking structure 50 comprises the RDL 18 disposed on the backside of the first die 12A, and conductive terminals 20 located on the RDL 18.

In some embodiments, within the peripheral region of the 3D stacking structure 50, the seal ring structures 1043A of the first die 12A and the seal ring structures 1043B of the second die 12B are arranged as ring-shapes respectively along the peripheral regions of the first die 12A and the second die 12B. Also, the seal ring structures 1043A and 1043B are substantially vertically aligned (along the thickness direction). As seen in FIG. 12, the dummy pads 1066A are located right above the seal ring structures 1043A in the peripheral region of the first die 12A, and the dummy pads 1066B are located right below the seal ring structures 1043B in the peripheral region of the second die 12B. In some embodiments, dummy pads 1066A of the first die 12A are directly bonded with the corresponding dummy pads 1066B of the second die 12B. Also, within the peripheral region of the 3D stacking structure 50, there is a metal pad-free zone DB1B of the insulation material 105B that has no metal pad or metal lines formed therein located right above the seal ring structures 1043B. In one embodiment, the metal-free zone DB1B may be a ring-shaped zone that surrounds the metal pads 1042B formed above the metallization structures 104B in the main device region.

Referring to FIG. 12, in some embodiments, nail vias 1065 extending between the dummy pads 1066A and the seal ring strictures 1043A physically connect the dummy pads 1066A and the seal ring strictures 1043A. The seal ring structures 1043A, the nail vias 1065, the bonded pairs of the dummy pads 1066A, 1066B are electrically floating, and the seal ring structures 1043B are electrically floating. In some embodiments, the nail vias 1065 do not function as electrical connection parts (i.e. not parts of the electrical connection path of the 3D stacking structure) and the nail vias 1065 connected with the seal ring structures 1043A may function as structural reinforcing element for enhancing structural integrity during dicing. Further, such structural reinforcing features are electrically isolated from the semiconductor devices within the 3D stacking structure.

In some embodiments, there is a pad-free zone (having no metal pad or aluminum pad formed in the zone) of the insulation material 105A, such pad-free zone is sandwiched between the dummy pads 1066A and the seal ring structures 1043A, but there are nail vias 1065 located in the pad-free zone (represented by the dash-lined rings). In one embodiment, such pad-free zone is not a metal-free zone or dielectric-only zone as nail vias are formed therein. Such pad-free zone formed with nail vias may function as cracking stopper as the nail vias enhances the structural resistance toward dicing and the pad-free zone without the metal pads lessens film delamination or cracking from the edges. In some embodiments, the nail vias 1065, the bonded pairs of the dummy pads 1066A, 1066B are substantially vertically aligned with the dielectric-only zone DB1B. As seen from the schematic view in the upper left part of FIG. 12, the metal-free zone DB1B (represented in dashed line) may be a ring-shaped zone overlapped with the ring-shaped seal ring structures 1043, and the dummy pads 1066B (along with the dummy pads 1066A and the nail vias 1065) are arranged along and located within the span of the metal-free zone DB1B. In some embodiments, the semiconductor devices 103A and 103B of the first and second dies 12A and 12B are electrically connected through the metallization structures 104A and 104B, the TSVs 1048B and the bonding pads 1062A and 1062B. In some embodiments, the conductive terminals 20 are electrically connected with the first die 12A through the RDL 18 and the TSVs 1048A of the first die 12A and are further electrically connected with the second die 12B through the metallization structures 104A, the bonding pads 1062A, 1062B, the metallization structures 104B and the TSVs 1048B.

In some embodiments, the 3D stacking structures 40 and 50 may be fabricated by using a wafer-on-wafer (WoW) process. Furthermore, the 3D stacking structures described above may be further bonded to a circuit substrate or used as package units and fabricated into 3D stacking packages or CoWoS packages, the disclosure is not limited to the package structure shown in the drawings.

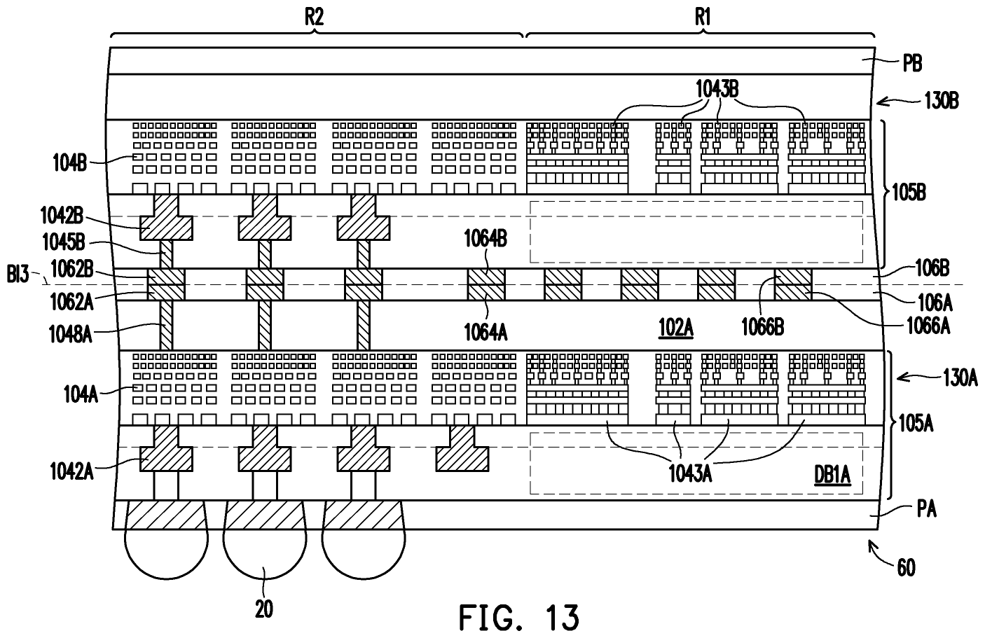

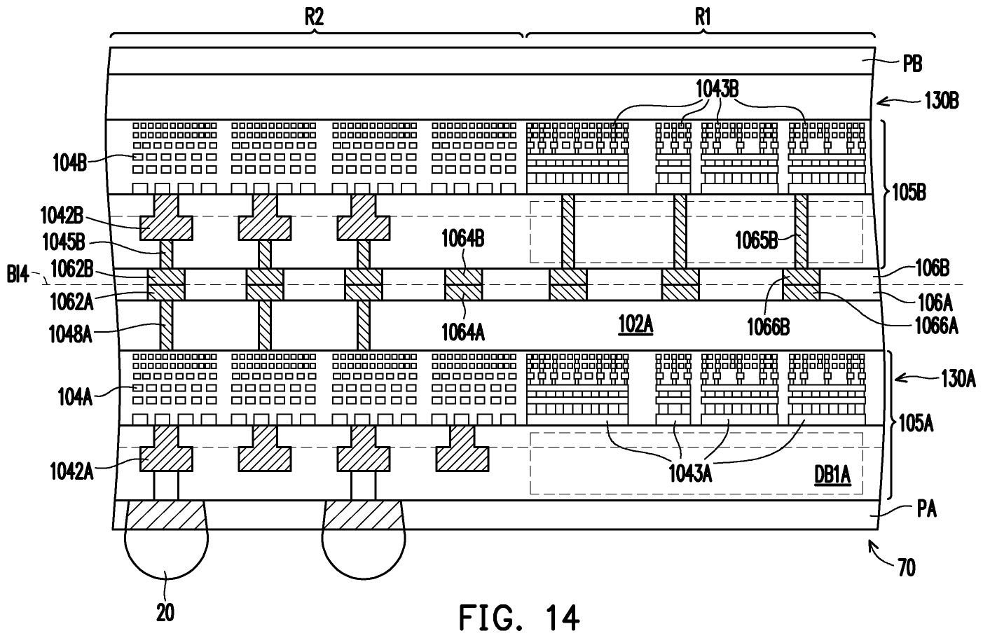

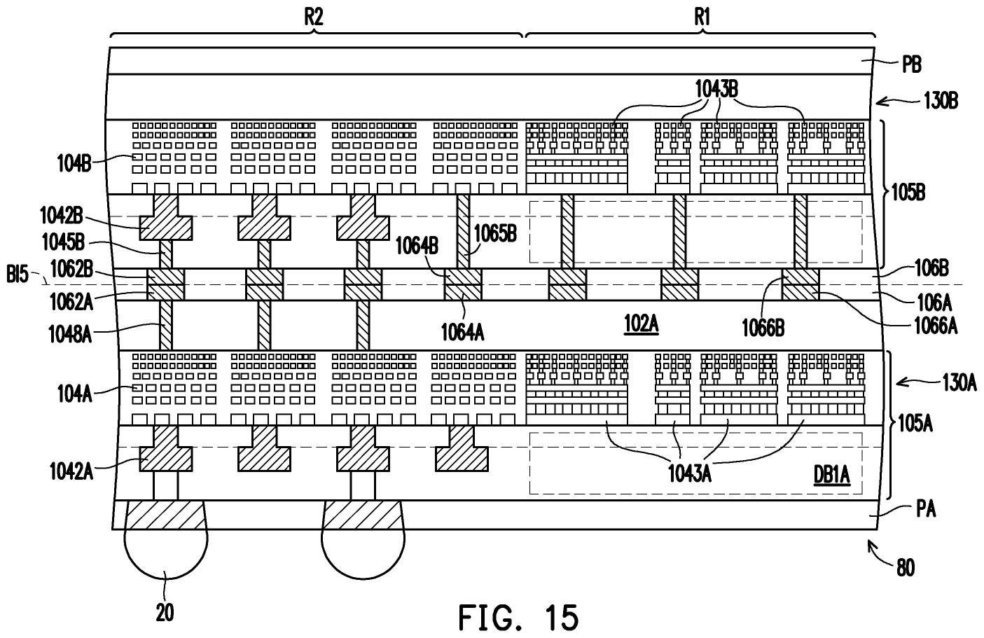

FIG. 13, FIG. 14 and FIG. 15 illustrate schematic cross-sectional views of portions of an exemplary 3D stacking structure in accordance with various embodiments of the present disclosure. In the following figures, the bonding portions of the first and second dies of the 3D stacking structures are enlarged for descriptions.

Referring to FIG. 13, in some embodiments, the 3D stacking structure 60 comprises bottom die 130A, top die 130B bonded with the bottom die 130A and passivation layers PA and PB covering the bottom and the top of the stacking structure 60. In some embodiments, located on the backside of the bottom die 130A, the bonding structure 106A includes bonding pads 1062A, dummy bonding pads 1064A and dummy pads 1066A embedded in the dielectric material 1061A. In some embodiments, located on the frontside of the top die 130B, the bonding structure 106B includes bonding pads 1062B, dummy bonding pads 1064B and dummy pads 1066B embedded in the dielectric material 1061B. With a hybrid bonding interface BI3, there is dielectric-to-dielectric bonding between the dielectric materials 1061A, 1061B and metallic-to-metallic bonding between the bonded pairs of the pads 1062A/1062B, 1064A/1064B and 1066A/1066B. In some embodiments, the dummy pads 1066A, 1066B are located within the first region R1 of the stacking structure, while the dummy bonding pads 1064A, 1064B and the bonding pads 1062A, 1062B are located within the second region R2. In some embodiments, the second region R2 is or includes a main region formed with devices, and the first region R1 is or includes a peripheral region having no active devices or passive devices formed therein.

Referring to FIG. 13, within the peripheral region R1 of the 3D stacking structure 60, there is a metal-free zone DB1A of the insulating material 105A that is sandwiched between the dummy pads 1066A and the seal ring structures 1043A, and there is a metal-free zone DB1B of the insulating material 105B that is sandwiched between the dummy pads 1066B and the seal ring structures 1043B. In some embodiments, the dielectric-only zones DB1B and DB1A are substantially vertically aligned (in the thickness direction). In some embodiments, as the electrical connection path, the metallization structures 104B and the contact pads 1042B in the second region R2 are connected with the bonding pads 1062B with the vias 1045B, and the bonding pads 1062A are connected with the metallization structures 104A and the contact pads 1042A through the TSVs 1048A. In some embodiments, the conductive terminals 20 are electrically connected with the contact pads 1042A for further electrical connection.

Referring to FIG. 14, in some embodiments, the 3D stacking structure 70 is similar to the stacking structure 60 of FIG. 13, and the same elements may be labelled with the same reference numbers. In some embodiments, the 3D stacking structure 70 has a hybrid bonding interface BI4, and there is dielectric-to-dielectric bonding between the dielectric materials 1061A, 1061B and metallic-to-metallic bonding between the bonded pairs of the bonding pads 1062A/1062B, dummy bonding pads 1064A/1064B and dummy pads 1066A/1066B. In some embodiments, the dummy pads 1066A, 1066B are located within the first region R1, while the dummy bonding pads 1064A, 1064B and the bonding pads 1062A, 1062B are located within the second region R2.

Referring to FIG. 14, within the peripheral region R1 of the 3D stacking structure 70, there is a metal-free zone DB1A that is sandwiched between the dummy pads 1066A and the seal ring structures 1043A, and there are nail vias (metallic vias) 1065B extending between and connecting the dummy pads 1066B and the seal ring structures 1043B. In some embodiments, the bonded pairs of dummy pads 1066A/1066B and the nail vias 1065B fall with the span of the dielectric-only zone DB1A. In some embodiments, the bonded pairs of dummy pads 1066A/1066B and the nail vias 1065B are connected to the seal ring structures 143B and are electrically floating. In some embodiments, there is a pad-free zone (having no metal pad or aluminum pad formed in the zone) of the insulation material 105B, such pad-free zone is sandwiched between the dummy pads 1066B and the seal ring structures 1043B, but there are nail vias 1065B located in the pad-free zone (represented by the dash-lined rings).

Referring to FIG. 15, in some embodiments, the 3D stacking structure 80 is similar to the stacking structure 70 of FIG. 14, and the same elements may be labelled with the same reference numbers. In some embodiments, in addition to the dummy pads 1066A. 1066B, there are nail vias 1065B located within the first region R1. Also, in addition to the dummy bonding pads 1064A, 1064B and the bonding pads 1062A, 1062B located within the second region R2, there are nail vias 1065B located in the second region R2. In some embodiments, the 3D stacking structure 80 has a hybrid bonding interface BI5, and there is dielectric-to-dielectric bonding between the dielectric materials 1061A. 1061B and metallic-to-metallic bonding between the bonded pairs of the bonding pads 1062A/1062B, dummy bonding pads 1064A/1064B and dummy pads 1066A/1066B.

Referring to FIG. 15, in the peripheral region R1, there is a metal-free zone DB1A that is sandwiched between the dummy pads 1066A and the seal ring structures 1043A, and nail vias (metallic vias) 1065B extend between and connect the dummy pads 1066B and the seal ring structures 1043B. In some embodiments, the bonded pairs of dummy pads 1066A/1066B and the nail vias 1065B connected to the seal ring structures 143B are electrically floating. In some embodiments, there is a pad-free zone (having no metal pad or aluminum pad formed in the zone) of the insulation material 105B, such pad-free zone is sandwiched between the dummy pads 1066B and the seal ring structures 1043B, but there are nail vias 1065B located in the pad-free zone (represented by the dash-lined rings). In some embodiments, the nail vias 1065B extend between the dummy bonding pads 1064B and the metallization structures 104B, as the dummy bonding pads 1064A/1064B are electrically floating pads, the nail vias 1065B connected with the dummy bonding pads 1064A/1064B are not part of the electrical connection path.

In some embodiments, relative to the bonding interface (represented by the dotted line), the additional dummy pads and/or the dummy bonding pads lead to more interfacial bonding pads and a more uniform layout design, which contributes to a more reliable interfacial bonding and less delamination around the edges of the package unit. Also, by way of eliminating the formation of aluminum pads on the seal ring structures in the peripheral region, film cracking near the die edge is minimized. In fact, the existence of the dielectric-only and metal-free zones may function as cracking stopper for the stacking structures.

In some embodiments of the present disclosure, a stacking structure is provided. The stacking structure includes a first die and a second die stacked on and bonded with the first die. The first die has a first region and a second region encircled by the first region. The first die includes first metallization structures embedded in a first insulating material and a first bonding structure located over the first insulating material and the first metallization structures. In the first region, the first metallization structures include a first seal ring structure and the first bonding structure includes first dummy pads located over the first seal ring structure. The second die includes second metallization structures embedded in a second insulating material and a second bonding structure located over the second insulation material and the second metallization structures. The second metallization structures include a second seal ring structure, and the second bonding structure includes second dummy pads located over the second seal ring structure. The first die and the second die are bonded through bonding of the first and second bonding structures. The first and second seal ring structures are substantially vertically aligned, and the first dummy pads are respectively bonded with the second dummy pads.

In some embodiments of the present disclosure, a stacking structure is provided. The stacking structure includes a first die, a second die stacked on and bonded with the first die, and a filling material over the first die. The first die has a first region and a second region encircled by the first region. The first die includes first metallization structures embedded in a first insulating material and a first bonding structure located over the first insulating material and the first metallization structures. In the first region, the first metallization structures include a first seal ring structure and the first bonding structure includes first dummy pads located over the first seal ring structure. The second die includes second metallization structures embedded in a second insulating material and a second bonding structure located over the second insulation material and the second metallization structures. The second metallization structures include a second seal ring structure, and the second bonding structure includes second dummy pads located over the second seal ring structure. The filling material is disposed on the first die and around the second die. The second bonding structure is bonded with the first bonding structure, the second seal ring structure is partially aligned with the first seal ring structure, and the second dummy pads are respectively bonded with the first dummy pads in the first region.

In some embodiments of the present disclosure, a method for forming stacking structures is described. A first wafer having first dies is provided. Each first die has a first region and a second region encircled by the first region. The first die includes first metallization structures embedded in a first insulating material and a first bonding structure located over the first insulating material and the first metallization structures. In the first region, the first metallization structures include a first seal ring structure and the first bonding structure includes first dummy pads located over the first seal ring structure in the first region and first bonding pads in the second region. Second dies are provided. The second die includes second metallization structures embedded in a second insulating material and a second bonding structure located over the second insulation material and the second metallization structures. The second metallization structures include a second seal ring structure, and the second bonding structure includes second dummy pads located over the second seal ring structure and second bonding pads. Third dies are provided. The third die includes third metallization structures embedded in a third insulating material and a third bonding structure located over the third insulation material and the third metallization structures. The third metallization structures include a third seal ring structure, and the third bonding structure includes third dummy pads located over the third seal ring structure and third bonding pads. The second and third dies are bonded with the first dies through the first, second and third bonding structures. The second and third dummy pads are respectively bonded with the first dummy pads and bonding the second and third bonding pads are respectively bonded with the first bonding pads. The second seal ring structure is partially aligned with the first seal ring structure, and the third seal ring structure is partially aligned with the first seal ring structure. A filling material is formed over the first wafer and covering the second and third dies. A singulation process is performed to cut through the filling material and the first wafer to form the stacking structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A stacking structure, comprising:
a first die having a first region and a second region encircled by the first region, wherein the first die includes first metallization structures embedded in a first insulating material and a first bonding structure located over the first insulating material and the first metallization structures, wherein, in the first region, the first metallization structures include a first seal ring structure and the first bonding structure includes first dummy pads located over the first seal ring structure; and
a second die stacked on and bonded with the first die, wherein the second die includes second metallization structures embedded in a second insulating material and a second bonding structure located over the second insulation material and the second metallization structures, wherein the second metallization structures include a second seal ring structure, and the second bonding structure includes second dummy pads located over the second seal ring structure,
wherein the first die and the second die are bonded through bonding of the first and second bonding structures, the first and second seal ring structures are substantially vertically aligned, and the first dummy pads are respectively bonded with the second dummy pads.

2. The structure of claim 1, wherein there is a first pad-free zone in the first insulation material located above the first seal ring structure and overlapped with the first seal ring structure.

3. The structure of claim 2, wherein the first pad-free zone is sandwiched between the first seal ring structure and the first dummy pads.

4. The structure of claim 2, wherein at least one nail via is located between and connects the second seal ring structure and at least one second dummy pad.

5. The structure of claim 2, wherein there is a second pad-free zone in the second insulation material located above the second seal ring structure and overlapped with the second seal ring structure.

6. The structure of claim 4, wherein the second pad-free zone is sandwiched between the second seal ring structure and the second dummy pads.

7. The structure of claim 1, wherein in the second region, the first bonding structure includes first bonding pads, and the second bonding structure includes second bonding pads, and the first bonding pads are respectively bonded with the second bonding pads, and the first and second dies are electrically connected through the first and second metallization structures and the first and second bonding pads.

8. The structure of claim 1, further comprising a redistribution structure disposed on the second die.

9. The structure of claim 8, wherein the second metallization structures include through semiconductor vias, and the redistribution structure is electrically connected with the second die via the through semiconductor vias.

10. A stacking structure, comprising:
a first die having a first region and a second region encircled by the first region, wherein the first die includes first metallization structures embedded in a first insulating material and a first bonding structure located over the first insulating material and the first metallization structures, wherein, in the first region, the first metallization structures include a first seal ring structure and the first bonding structure includes first dummy pads located over the first seal ring structure;
a second die stacked on and bonded with the first die, wherein the second die includes second metallization structures embedded in a second insulating material and a second bonding structure located over the second insulation material and the second metallization structures, wherein the second metallization structures include a second seal ring structure, and the second bonding structure includes second dummy pads located over the second seal ring structure; and
a filling material disposed on the first die and around the second die,
wherein the second bonding structure is bonded with the first bonding structure, the second seal ring structure is partially aligned with the first seal ring structure, and the second dummy pads are respectively bonded with the first dummy pads in the first region.

11. The structure of claim 10, further comprising a redistribution structure disposed on the second die, and the redistribution structure is electrically connected with through semiconductor vias of the second die.

12. The structure of claim 10, wherein there is a first pad-free zone in the first insulation material sandwiched between the first seal ring structure and the first dummy pads and overlapped with the first seal ring structure.

13. The structure of claim 12, wherein at least one nail via is located between and connects the second seal ring structure and at least one second dummy pad.

14. The structure of claim 12, wherein there is a second pad-free zone in the second insulation material sandwiched between the second seal ring structure and the second dummy pads and overlapped with the second seal ring structure, and the first and second pad-free zones within the first region are aligned.

15. The structure of claim 14, further comprising a third die stacked on and bonded with the first die, wherein the third die includes third metallization structures embedded in a third insulating material and a third bonding structure located over the third insulation material and the third metallization structures, wherein the third metallization structures include a third seal ring structure, and the third bonding structure includes third dummy pads located over the third seal ring structure, there is a third pad-free zone in the third insulation material sandwiched between the third seal ring structure and the third dummy pads and overlapped with the third seal ring structure, and the first and third pad-free zones within the first region are aligned.

16. The structure of claim 15, wherein in the second region, the first bonding structure includes first bonding pads, the second bonding structure includes second bonding pads, the third bonding structure includes third bonding pads, and the second and third bonding pads are respectively bonded with the first bonding pads, and the first, second and third dies are electrically connected through the first, second and third metallization structures and the first, second and third bonding pads.

17. A method for forming stacking structures, comprising:
providing a first wafer having first dies, each first die having a first region and a second region encircled by the first region, wherein the first die includes first metallization structures embedded in a first insulating material and a first bonding structure located over the first insulating material and the first metallization structures, wherein, in the first region, the first metallization structures include a first seal ring structure and the first bonding structure includes first dummy pads located over the first seal ring structure in the first region and first bonding pads in the second region;
providing second dies, wherein the second die includes second metallization structures embedded in a second insulating material and a second bonding structure located over the second insulation material and the second metallization structures, wherein the second metallization structures include a second seal ring structure, and the second bonding structure includes second dummy pads located over the second seal ring structure and second bonding pads;
providing third dies, wherein the third die includes third metallization structures embedded in a third insulating material and a third bonding structure located over the third insulation material and the third metallization structures, wherein the third metallization structures include a third seal ring structure, and the third bonding structure includes third dummy pads located over the third seal ring structure and third bonding pads;
bonding the second and third dies with the first dies through the first, second and third bonding structures, wherein the second and third dummy pads are respectively bonded with the first dummy pads and bonding the second and third bonding pads are respectively bonded with the first bonding pads, wherein the second seal ring structure is partially aligned with the first seal ring structure, and the third seal ring structure is partially aligned with the first seal ring structure, and;
forming a filling material over the first wafer and covering the second and third dies; and
performing a singulation process to cut through the filling material and the first wafer to form the stacking structures.

18. The method of claim 17, wherein the filling material is formed over the first wafer and is in contact with at least one first dummy pad.

19. The method of claim 17, wherein bonding the second and third dies with the first dies through the first, second and third bonding structures includes metallic bonding between the first, second and third dummy pads and the first, second and third bonding pads and dielectric bonding between dielectric materials of the first, second and third bonding structures.

20. The method of claim 9, further comprising forming a redistribution layer on the second and third dies and the filling material, and forming conductive terminals on the redistribution layer.
